(19) United States
(12) Patent Application Publication
(10) Pub. No.: US 2007/0020395 A1
(43) Pub. Date: Jan. 25, 2007

(54) Process for making an electronic device

(76) Inventors: Charles D. Lang, Goleta, CA (US); Jeffrey Glenn Innocenzo, Towanda, PA (US); Alberto Goenaga, Goleta, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/475,701

(22) Filed: Jun. 27, 2006

Related U.S. Application Data
(60) Provisional application No. 60/694,280, filed on Jun. 27, 2005.
(60) Provisional application No. 60/694,276, filed on Jun. 27, 2005.

(51) Int. Cl. B05D 5/00; B05D 3/12

(52) U.S. Cl. 427/256; 427/356

(57) ABSTRACT

There is provided a process for forming a workpiece comprising a first layer and a second layer, said process comprising (i) forming a patterned first layer having at least one pattern area comprising a first material having a first critical surface tension surrounded by a second layer comprising a second material having a second critical surface tension greater than the first critical surface tension; (ii) depositing a liquid composition comprising a third material in a liquid medium over the pattern area of the first layer and a portion of the second layer; wherein the third material is deposited by a pre-metered coating method. The pattern area in the first layer may be continuous or be composed of discrete deposits of the first material on a substrate. The workpiece so formed is useful in electronic devices including OLEDs.

### RELATED U.S. APPLICATIONS

This application claims priority to U.S. provisional application Ser. No. 60/694276, filed Jun. 27, 2005.

### BACKGROUND INFORMATION

1. Field of the Disclosure

This disclosure relates in general to a process for making an electronic device. In particular, it relates to a method including a coating step using a pre-metered coating technique.

2. Description of the Related Art

Increasingly, active organic molecules are used in electronic devices. These active organic molecules have electronic or electro-radiative properties including electroluminescence. Electronic devices that incorporate organic active materials may be used to convert electrical energy into radiation and may include a light-emitting diode, light-emitting diode display, or diode laser.

Two methods are commonly used to prepare organic light-emitting diode (“OLED”) displays: vacuum deposition, and solution processing. (The latter includes all forms of applying the layers from a fluid, as a true solution or a suspension.) Vacuum deposition equipment typically has very high investment costs, and inferior material utilization (high operating costs), so solution processing is preferred, especially for large area displays.

Liquid processes for the deposition of organic active layers include self-metered and pre-metered processes. Self-metered techniques include spin coating, rod coating, dip coating, roll coating, gravure coating or printing, lithographic or flexographic printing, screen coating or printing, etc. Pre-metered techniques include ink jet printing, spray coating, nozzle coating, slot die coating, curtain coating, bar or slide coating, etc.

Self-metered techniques suffer a number of drawbacks. Fluids used in coating OLED displays are often applied over surfaces with topography—electrodes, contact pads, thin film transistors, pixel wells formed from photoresists, cathode separator structures, etc. The uniformity of the wet layer deposited by a self-metered technique depends on the coating gap and resulting pressure distribution, so variations in the substrate topography result in undesirable variations in the wet coating thickness. Self-metered techniques generally suffer higher operating costs in that not all the fluid presented to the substrate is deposited. Some fluid is either recycled in the fluid bath (e.g., dip coating), or on the applicator (e.g., roll or gravure coating), or, it is wasted (e.g., spin coating). Solvent evaporates from the recycled fluid, requiring adjustment to maintain process stability. Wasting material, and recycling and adjusting material, add cost.

Pre-metered techniques can provide lower operating cost. However, in some cases, poor wetting of underlying organic layers may lead to thickness variations or even voids within the organic active layer. Inconsistent formation of organic active layers typically leads to poor device performance and poor yield in device fabricating processes.

There continues to be a need for improved processes for the solution deposition of organic active materials.

### SUMMARY

There is provided a process for forming a workpiece comprising a patterned first layer comprising a first material and a second layer comprising a second material, said process comprising:

forming a patterned first layer having at least one pattern having a first critical surface tension is surrounded by a second layer having a second critical surface tension greater than the first critical surface tension;

depositing a liquid composition comprising a third material in a liquid medium over the pattern area of the first layer and a portion of the second layer;

wherein said third material is deposited by a pre-metered coating method.

In one embodiment, there is provided a process in which the pre-metered coating method is a slot die coating method.

In another embodiment, there is provided a process in which the workpiece is an electronic device.

In another embodiment, there is provided a process in which the workpiece is an organic light-emitting diode.

The foregoing general description and the following detailed description are exemplary and explanatory only and are not restrictive of the invention, as defined in the appended claims.

### BRIEF DESCRIPTION OF THE DRAWINGS

The invention is illustrated by way of example and not limitation in the accompanying figures.

FIG. 1 is a schematic diagram illustrating one embodiment of the new process.

FIG. 2 is a schematic diagram of one illustrative embodiment of a light-emitting device.

FIG. 3 is a schematic diagram illustrating a comparative process.

FIG. 4 is a schematic diagram illustrating one embodiment of the new process.

FIG. 5 is a schematic diagram illustrating a comparative process.

FIG. 6 is a schematic diagram illustrating one embodiment of the new process.

Skilled artisans appreciate that objects in the figures are illustrated for simplicity and clarity and have not necessarily been drawn to scale. For example, the dimensions of some of the objects in the figures may be enlarged relative to other objects to help to improve understanding of embodiments.

### DETAILED DESCRIPTION

There is provided a process for forming a workpiece comprising a patterned first layer comprising a first material and a second layer comprising a second material, said process comprising

forming a patterned first layer having at least one pattern area area having a first critical surface tension is surrounded by a second layer having a second critical surface tension greater than the first critical surface tension;

depositing a liquid composition comprising a third material in a liquid medium over the pattern area of the first layer and a portion of the second layer; wherein said third material is deposited by a pre-metered coating method.

Many aspects and embodiments are described in the specification and are exemplary and not limiting. After reading this specification, skilled artisans will appreciate that other aspects and embodiments are possible without departing from the scope of the disclosure and the appended claims.

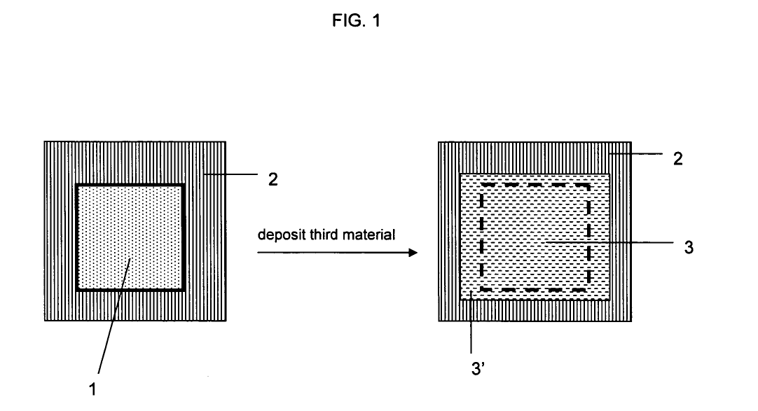

In the disclosed process, the third material is deposited over at least the first material and a portion of the second material. Thus, the third material completely covers the first material and extends beyond the pattern of the first material to cover a portion of the second material. This may be better understood by reference to FIG. 1, which is an exemplary representation of the process. The pattern area of the first material (layer) 1 is surrounded by second material (layer) 2. In this depiction, the pattern area of the first layer is continuous, so that the pattern area is coextensive with the first layer. After depositing the third material, 3, the first material (pattern area of the first layer 1) is completely covered. A part of the second material 2 is also covered forming a covered border, 3′, around the first material.

In a pre-metered coating method all the fluid supplied to the coating applicator is applied to the substrate or workpiece. The average wet coating thickness can be calculated a priori from the volumetric flow rate of the coating fluid, the coated width, and the speed at which the substrate moves past the applicator. Fluid properties (e.g., viscosity, surface tension) and external forces (e.g., gravity) may affect the quality of the coating, but they do not affect the average wet thickness. Examples of pre-metered coating methods include, but are not limited to, ink jet printing, spray coating, nozzle coating, slot die coating, curtain coating, bar coating, and slide coating.

In contrast, in self-metered coating methods, an excess of fluid is supplied to the substrate, and the excess is recycled or discarded. Fluid properties generally influence the wet coating thickness obtained from a self-metered process; external forces may also affect the coating thickness (e.g., gravity is a significant force in dip coating). Examples of self-metered coating methods include spin coating, rod coating, dip coating, roll coating, gravure coating or printing, lithographic printing, flexographic printing, and screen coating or printing.

These definitions apply to steady-state production of coatings with acceptable quality. Frivolous situations such as start-up when the fluid delivery systems are being filled, and operation where the coating is grossly defective do not satisfy these definitions.

As used herein, the term “workpiece” is intended to mean a substrate at any particular point of a process sequence. The term “substrate” is intended to mean a base material that can be either rigid or flexible and may be include one or more layers of one or more materials, which can include, but are not limited to, glass, polymer, metal or ceramic materials or combinations thereof. The reference point for a substrate is the beginning point of a process sequence. The substrate may or may not include electronic components, circuits, or conductive members. The term “patterned”, with respect to a layer, is intended to mean a layer that does not cover the entire surface of the underlying workpiece. The term “critical surface tension” with respect to a solid, is intended to mean the surface tension above which a liquid cannot completely wet the solid. The term “liquid composition” is intended to mean a liquid medium in which a material is dissolved to form a solution, a liquid medium in which a material is dispersed to form a dispersion, or a liquid medium in which a material is suspended to form a suspension or an emulsion. The term “liquid medium” is intended to mean a liquid material, including a pure liquid, a combination of liquids, a solution, a dispersion, a suspension, and an emulsion. Liquid medium is used regardless whether one or more solvents are present. The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

In one embodiment, the first material is applied to a layer of second material in a pattern. In one embodiment, the first material is applied as a continuous layer over the second material, and then portions of the first material are removed to form the pattern. In one embodiment, the first material is applied to the workpiece as a continuous layer, and the second material is applied in a pattern over the first material to create the pattern of first material. In one embodiment, the first material is applied to the workpiece in a pattern, and the second material is applied to the workpiece in the unpatterned areas where there is no first material.

The first and second materials are selected to have the properties desired for the finished workpiece, and also so that the second material has a critical surface tension that is greater than the critical surface tension of the first material. The critical surface tension of a layer is an intrinsic property that can be estimated from a Zisman plot. A Zisman plot is a graphical representation to determine the critical surface tension of a solid (in fact the free surface energy) according to W. A. Zisman (1950-52). The plot is made by plotting the cosine of the contact angle versus the surface tension of various wetting liquids on a given solid. The abscissa (x-axis) carries the surface tensions of the test liquids used, the ordinate (y-axis) carries in contrast the cosine of the measured contact angle. The resulting plot is a straight line. Thus, there exists some unique value for each polymeric solid where the cosine of the contact angle is unity. The specific value on the abscissa for which the cosine is one, is called the critical surface tension. A liquid with surface tension below the critical value will wet and spread over the solid surface, whereas a liquid with surface tension above the critical value might wet, but won't spread. The critical surface tension is measured in units of dyne/cm.

In one embodiment, the critical surface tension of the second material is at least 5 dyne/cm greater than the critical surface tension of the first material. In one embodiment, the critical surface tension of the second material is at least 10 dyne/cm greater than the critical surface tension of the first material. In one embodiment, the critical surface tension of the second material is at least 15 dyne/cm greater than the critical surface tension of the first material. In one embodiment, the critical surface tension of the second material is at least 25 dyne/cm than that of the first material. In one embodiment, the critical surface tension of the second material is at least 30 dyne/cm greater than that of the first.

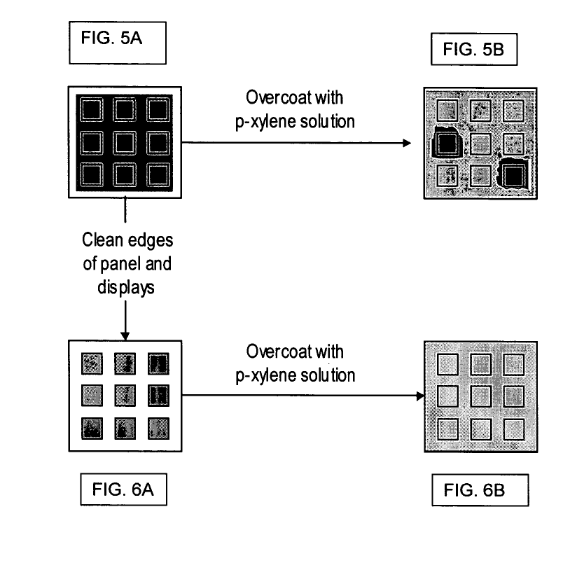

In one embodiment, the patterned first layer is formed by depositing discrete areas of the first material over a substrate, wherein the substrate has a critical surface tension greater than the first material critical surface tension. The first layer can be deposited by any conventional technique, including vapor deposition, liquid deposition, and thermal transfer. In one embodiment, the first layer is deposited as discrete patches, each of which is surrounded by uncovered areas of the underlying substrate. FIGS. 5A and 6A (and their finished forms, depicted in FIGS. 5B and 6B) illustrate an embodiment in which the pattern areas of the first material are discontinuous, and each discrete pattern area is surrounded by the second material. In one embodiment, the underlying substrate further comprises one or more additional layers. The additional layers can be patterned or unpatterned. When additional layers are present, the material in the areas surrounding the first material is considered the second material.

In one embodiment, the patterned first layer is formed by liquid deposition. The first material is deposited from a first material liquid composition comprising the first material in a liquid medium. In one embodiment, the first material liquid composition is deposited by a pre-metered coating method. In one embodiment, the first material liquid composition is applied using a manifold to distribute the first material liquid composition laterally across the width of the substrate being coated, with a slot to form a liquid bridge or meniscus between the manifold and the substrate. In one embodiment, the first material liquid composition is deposited using a slot die coating method.

In one embodiment, the patterned first layer is formed by first forming an overall, unpatterned layer, and then removing areas of the layer to form the pattern. The overall layer can be formed by any conventional technique, including vapor deposition, liquid deposition, and thermal transfer. Areas of the layer can be removed by any conventional technique, including chemical etching, plasma etching, laser ablation and the like. A conventional photoresist mask can be used to create the pattern.

In one embodiment, the pattern of first material is a multiplicity of discrete patches. In one embodiment, the patches are rectangular. In one embodiment, the patches are square. In one embodiment, the patches are oval or circular. In one embodiment, the pattern is a multiplicity of stripes. Other regular or irregular shapes can be used for the pattern.

In one embodiment, the second material is applied over the first material to form the pattern of the first material. The second material can be deposited by any conventional technique, including vapor deposition, liquid deposition, and thermal transfer. In one embodiment, the second layer is deposited to form discrete patches of first material, each of which is surrounded by areas of the overlying second material.

In one embodiment, the liquid composition comprising the third material in a liquid medium is deposited over the first material and at least a part of the second material, to form a film approximating its final shape, so that flows driven by surface tension or gravity can be minimized. In this regard, ink jet printing, nozzle and spray coating are not preferred as the liquid is delivered in the form of drops or cylinders that must then flow out to assume the final desired flat-film shape. In one embodiment, the liquid composition is applied using a manifold to distribute the liquid composition laterally across the width of the substrate being coated, with a slot to form a liquid bridge or meniscus between the manifold and the substrate. In one embodiment, the liquid composition is deposited using a slot die coating method. Of the pre-metered film-coating techniques, slot die coating operates across wide ranges of fluid viscosities, coating speeds, wet thickness, and coating width. In general, in slot die coating, a coating liquid is forced out from a reservoir through a slot by pressure, and transferred to a substrate moving relative to the die. In practice, the slot is generally much smaller in section than the reservoir. Slot die coating has many variations, including design of the die itself, orientation of the die to the substrate, “on roll” versus “off roll”, “patch coating” versus “continuous coating”, “stripe coating”, and the method of generating the pressure which forces liquid out of the die. Slot die coating is generally recognized to be coating with a die “against” a substrate, in which the die is actually separated from the substrate by a cushion of liquid being coated. Further discussions of slot die coating and apparatus can be found in, for example, Kistler, S. F., and Schweizer, P. M., “Liquid Film Coating,” Chapman & Hall, 1997.

In one embodiment, the workpiece comprises a substrate (such as glass) useful for an organic electronic device. The term “organic electronic device” or sometimes just “electronic device”, is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

In one embodiment, the workpiece is a rigid substrate with a transparent electrode deposited thereon. In one embodiment, the workpiece is a glass substrate with an electrode that is indium tin oxide (“ITO”).

In one embodiment, the organic electronic device comprises an organic active layer positioned between two electrical contact layers, wherein at least part of the device is made according to the new process. The term “active” when referring to a layer or material is intended to mean a layer or material that exhibits electronic or electro-radiative properties. An active layer material may emit radiation or exhibit a change in concentration of electron-hole pairs when receiving radiation. In one embodiment, the active layer is photoactive. The term “photoactive” is intended to refer to any material that exhibits electroluminescence or photosensitivity.

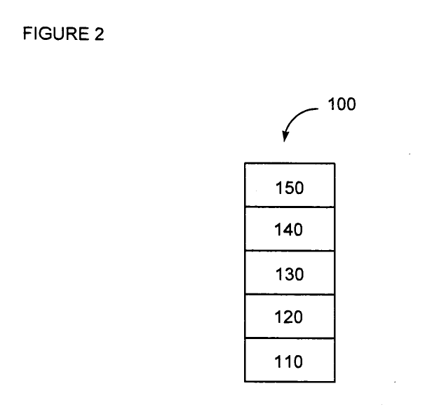

One embodiment is an organic light-emitting diode (“OLED”), as shown in FIG. 2. The device has an anode layer 110, a buffer layer 120, a photoactive layer 130, and a cathode layer 150. Adjacent to the cathode layer 150 is an optional electron-injection/transport layer 140. Between the buffer layer 120 and the photoactive layer 130, is an optional hole-injection/transport layer (not shown).

As used herein, the term “buffer layer” or “buffer material” is intended to mean electrically conductive or semiconductive materials that may have one or more functions in an organic electronic device, including but not limited to, planarization of the underlying layer, charge transport and/or charge injection properties, scavenging of impurities such as oxygen or metal ions, and other roles, such as to facilitate or improve the performance of the organic electronic device. Buffer materials may be polymers, oligomers, or small molecules, and may be in the form of solutions, dispersions, suspensions, emulsions, colloidal mixtures, or other compositions. The term “hole transport” when referring to a layer, material, member, or structure, is intended to mean that such layer, material, member, or structure facilitates migration of positive charges through the thickness of such layer, material, member, or structure with relative efficiency and small loss of charge. The term “electron transport” when referring to a layer, material, member or structure, is intended to mean that such layer, material, member or structure promotes or facilitates migration of negative charges through such a layer, material, member or structure into another layer, material, member or structure. The term “hole injection” when referring to a layer, material, member, or structure, is intended to mean that such layer, material, member, or structure facilitates injection and migration of positive charges through the thickness of such layer, material, member, or structure with relative efficiency and small loss of charge. The term “electron injection” when referring to a layer, material, member, or structure, is intended to mean that such layer, material, member, or structure facilitates injection and migration of negative charges through the thickness of such layer, material, member, or structure with relative efficiency and small loss of charge.

The device may include a support or substrate (not shown) that can be adjacent to the anode layer 110 or the cathode layer 150. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 150. The anode can include materials containing a metal, mixed metal, alloy, metal oxide or mixed oxide. Suitable materials include the mixed oxides of the Group 2 elements, the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, gold, silver, copper, and nickel. The anode may also comprise an organic material such as polyaniline, polythiophene, or polypyrrole. The IUPAC number system is used throughout, where the groups from the Periodic Table are numbered from left to right as 1-18 (CRC Handbook of Chemistry and Physics, 81^{st} Edition, 2000).

The anode layer 110 may be formed by a chemical or physical vapor deposition process or spin-coating process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

The anode layer 110 may be patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

In one embodiment, the buffer layer 120 comprises hole transport materials. Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); a-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (a-NPB); and porphyrinic compounds, such as copper phthalocyanine. Commonly used hole transporting polymers include, but are not limited to, poly(9,9,-dioctyl-fluorene-co-N-(4-butylphenyl)diphenylamine), and the like, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In one embodiment, the buffer material comprises an electrically conductive polymer and a fluorinated acid polymer (“ECP/FAP”). The term “electrically conductive polymer” refers to any polymer or oligomer which is inherently or intrinsically capable of electrical conductivity without the addition of carbon black or conductive metal particles. The term “polymer” encompasses homopolymers and copolymers. The term “electrical conductivity” includes conductive and semi-conductive. The term “fluorinated acid polymer” refers to a polymer having acidic groups, where at least some of the hydrogens on the polymeric backbone, side chains or pendant groups, or combinations of those, have been replaced by fluorine. The term “acidic group” refers to a group capable of ionizing to donate a hydrogen ion to a base to form a salt.

In one embodiment, the ECP is selected from polythiophenes, polypyrroles, polyanilines, polycyclic aromatic polymers, copolymers thereof, and combinations thereof. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring.

In one embodiment, the FAP is selected from organic solvent wettable fluorinated acid polymers and organic solvent non-wettable fluorinated acid polymers. The term “organic solvent wettable” refers to a material which, when formed into a film, is wettable by organic solvents. In one embodiment, the film of the organic solvent wettable material is wettable by phenylhexane with a contact angle less than 40°. The term “organic solvent non-wettable” refers to a material which, when formed into a film, is not wettable by organic solvents. In one embodiment, the film of the organic solvent non-wettable material is wettable by phenylhexane with a contact angle greater than 40°.

In the FAP, the acidic group can be attached directly to the polymer backbone, or it can be attached to side chains on the polymer backbone. In one embodiment, the polymer backbone is fluorinated. Examples of suitable polymeric backbones include, but are not limited to, polyolefins, polyacrylates, polymethacrylates, polyimides, polyamides, polyaramids, polyacrylamides, polystyrenes, and copolymers thereof. In one embodiment, the polymer backbone is highly fluorinated. In one embodiment, the polymer backbone is fully fluorinated.

In one embodiment, the acidic groups are selected from sulfonic acid groups and sulfonimide groups. In one embodiment, the acidic groups are on a fluorinated side chain. In one embodiment, the fluorinated side chains are selected from alkyl groups, alkoxy groups, amido groups, ether groups, and combinations thereof. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the FAP may have more than one type of acidic group.

In one embodiment, the organic solvent wettable FAP is water-soluble. In one embodiment, the organic solvent wettable FAP is dispersible in water.

In one embodiment, the organic solvent non-wettable FAP is a colloid-forming polymeric acid. As used herein, the term “colloid-forming” refers to materials which are insoluble in water, and form colloids when dispersed into an aqueous medium. The colloid-forming polymeric acids typically have a molecular weight in the range of about 10,000 to about 4,000,000. In one embodiment, the polymeric acids have a molecular weight of about 100,000 to about 2,000,000. Colloid particle size typically ranges from 2 nanometers (nm) to about 140 nm. In one embodiment, the colloids have a particle size of 2 nm to about 30 nm.

In one embodiment, the ECP/FAP is formed by oxidative polymerization of the ECP monomer or monomers in the presence of the FAP. In one embodiment, the ECP/FAP is formed by first forming the ECP by oxidative polymerization of the ECP monomer or monomers in the presence of a non-fluorinated polymeric acid, and then blending the resulting polymer with the FAP. Blends of ECP/FAP materials can be used.

In one embodiment, the ECP is selected from poythiophenes, polyanilines, and polypyrroles, and the FAP is a colloid-forming polymeric acid. Such materials have been described in published PCT applications WO 2004/029128, WO 2004/029133, and WO 2004/029176.

The photoactive layer 130 may typically be any organic electroluminescent (“EL”) material, including, but not limited to, small molecule organic fluorescent compounds, fluorescent and phosphorescent metal complexes, conjugated polymers, and combinations or mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof.

Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and may further include combinations or mixtures thereof.

The choice of a particular material may depend on the specific application, potentials used during operation, or other factors. The EL layer 130 containing the electroluminescent organic material can be applied using any number of techniques including vapor deposition, solution processing techniques or thermal transfer. In another embodiment, an EL polymer precursor can be applied and then converted to the polymer, typically by heat or other source of external energy (e.g., visible light or UV radiation).

Optional layer 140 can function both to facilitate electron injection/transport, and can also serve as a confinement layer to prevent quenching reactions at layer interfaces. More specifically, layer 140 may promote electron mobility and reduce the likelihood of a quenching reaction if layers 130 and 150 would otherwise be in direct contact. Examples of materials for optional layer 140 include, but are not limited to, include metal chelated oxinoid compounds, such as tris(8-hydroxyquinolato)aluminum (Alq3), bis(2-methyl-8-quinolinolato)(para-phenyl-phenolato)aluminum(III) (BAIQ), and tetrakis-(8-hydroxyquinolinato)zirconium (IV) (ZrQ) ; and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. Alternatively, optional layer 140 may be inorganic and comprise BaO, LiF, Li₂O, or the like.

The cathode layer 150 is an electrode that is particularly efficient for injecting electrons or negative charge carriers. The cathode layer 150 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 150 include, but are not limited to, barium, lithium, cerium, cesium, europium, rubidium, yttrium, magnesium, samarium, and alloys and combinations thereof.

The cathode layer 150 is usually formed by a chemical or physical vapor deposition process. In general, the cathode layer will be patterned, as discussed above in reference to the anode layer 110. If the device lies within an array, the cathode layer 150 may be patterned into substantially parallel strips, where the lengths of the cathode layer strips extend in substantially the same direction and substantially perpendicular to the lengths of the anode layer strips. Electronic elements called pixels are formed at the cross points (where an anode layer strip intersects a cathode layer strip when the array is seen from a plan or top view).

In other embodiments, additional layer(s) may be present within organic electronic devices. For example, a layer (not shown) between the buffer layer 120 and the EL layer 130 may facilitate positive charge transport, band-gap matching of the layers, function as a protective layer, or the like. Similarly, additional layers (not shown) between the EL layer 130 and the cathode layer 150 may facilitate negative charge transport, band-gap matching between the layers, function as a protective layer, or the like. Layers that are known in the art can be used. In addition, any of the above-described. layers can be made of two or more layers. Alternatively, some or all of inorganic anode layer 110, the buffer layer 120, the EL layer 130, and cathode layer 150, may be surface treated to increase charge carrier transport efficiency. The choice of materials for each of the component layers may be determined by balancing the goals of providing a device with high device efficiency with the cost of manufacturing, manufacturing complexities, or potentially other factors.

The different layers may have any suitable thickness. In one embodiment, inorganic anode layer 110 is usually no greater than approximately 500 nm, for example, approximately 10-200 nm; buffer layer 120, is usually no greater than approximately 250 nm, for example, approximately 50-200 nm; EL layer 130, is usually no greater than approximately 100 nm, for example, approximately 50-80 nm; optional layer 140 is usually no greater than approximately 100 nm, for example, approximately 20-80 nm; and cathode layer 150 is usually no greater than approximately 100 nm, for example, approximately 1-50 nm. If the anode layer 110 or the cathode layer 150 needs to transmit at least some light, the thickness of such layer may not exceed approximately 100 nm.

In organic light emitting diodes (OLEDs), electrons and holes, injected from the cathode 150 and anode 110 layers, respectively, into the EL layer 130, form negative and positively charged polar ions in the polymer. These polar ions migrate under the influence of the applied electric field, forming a polar ion exciton with an oppositely charged species and subsequently undergoing radiative recombination. A sufficient potential difference between the anode and cathode, usually less than approximately 12 volts, and in many instances no greater than approximately 5 volts, may be applied to the device. The actual potential difference may depend on the use of the device in a larger electronic component or device. In many embodiments, the anode layer 110 is biased to a positive voltage and the cathode layer 150 is at substantially ground potential or zero volts during the operation of the electronic device. A battery or other power source(s) may be electrically connected to the electronic device as part of a circuit but is not illustrated in FIG. 2.

In one embodiment of the new process described herein, the first material comprises a buffer material, the second material comprises anode material, and the third material comprises a photoactive material. The buffer layer 120 is formed in a pattern over the anode layer 110. The photoactive material is then deposited over the buffer layer and at least a portion of the anode by a pre-metered coating method. In one embodiment, the buffer layer comprises a material having a critical surface tension less than about 20 dyne/cm. In one embodiment, the buffer layer comprises a fluorinated material. In one embodiment, the pre-metered coating method comprises using a manifold to distribute the liquid composition laterally across the buffer layer, with a slot to form a liquid meniscus between the manifold and the buffer layer. In one embodiment, the pre-metered coating method comprises slot die coating.

In one embodiment, the buffer layer 120, comprising a fluorinated material, is deposited as a liquid composition in a pattern of discrete patches over a substrate having a patterned anode. After drying, a liquid composition comprising a photoactive material in a liquid medium is coated over each patch of buffer material and extending beyond the buffer material on all sides. The photoactive material is deposited using a slot die coating method. Devices suitable for dispensing organic material are pre-metered.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

### EXAMPLES

In the following examples, the fluorinated buffer material was an aqueous dispersion of poly(ethylendioxythiophene) and a poly(perfluoroalkylenesulfonic acid), as described in published PCT application WO 2004/029128. The critical surface tension of a film of the fluorinated buffer material was about 15 dyne/cm, as estimated from a Zisman plot.

### Example 1

This example demonstrates the economic advantages of using slot die coating (an example of pre-metered deposition method) vs. spin coating to prepare OLED displays.

Glass substrates (an example of self-metered deposition method-Corning 1737) with a coating of indium tin oxide (“ITO”) were cleaned via uv-ozone treatment for 3 minutes. An aqueous suspension of fluorinated buffer material was coated on one glass substrate using spin coating. About 20 ml of fluorinated buffer material suspension was required to achieve complete coverage of the substrate via spin coating. A similar coating of fluorinated buffer material was prepared on ITO/glass substrate using a slot die (FAS Technologies). Less than 1 ml of fluorinated buffer material was required to achieve the similar dried coatings. This implies material savings of about 95% vs. spin coating.

### Example 2

This example demonstrates a means of coating over a buffer layer containing a fluorinated material via slot die coating.

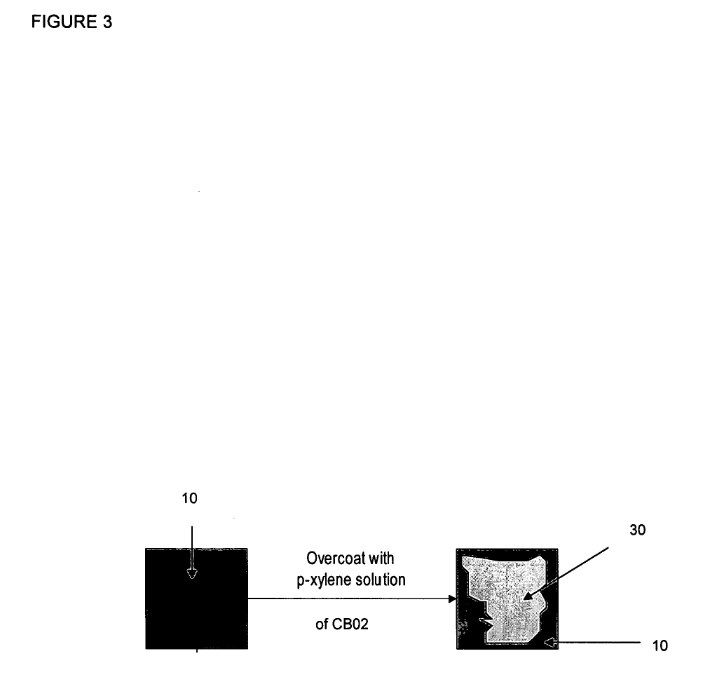

ITO/glass substrates similar to those in example 1 were cleaned via UV-ozone treatment, and coated with fluorinated buffer material, as in Example 1. The substrates coated with fluorinated buffer material were dried on an oven shelf at 130° C. for 3 minutes. The electroluminescent material was a polymer from Covion Organic Semiconductors GmbH, Frankfurt, Germany (“CB02”). A solution of CB02 (1.2% solids in p-xylene) was coated over a first fluorinated buffer material-coated substrate at a wet thickness of about 10 μm; the CB02 solution de-wet from regions of the coating due to surface tension, resulting in a defective and incomplete film of CB02. This is shown schematically in FIG. 3, where the buffer material is indicated by the numeral 10 and the CB02 is indicated by the numeral 30.

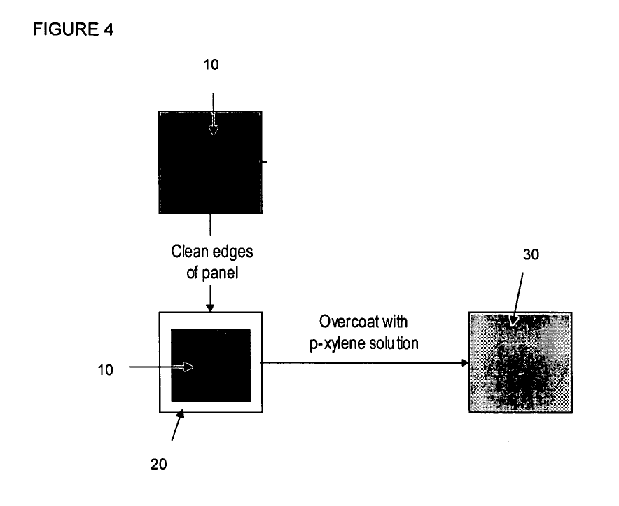

Using a wiping cloth soaked with water, and then a separate cloth soaked with isopropanol, the fluorinated buffer material was removed from the margins of a third substrate coated with fluorinated buffer material to reveal about ¾″ of clean glass framing the patch of fluorinated buffer material. The CB02 solution was then coated over the entire patch of fluorinated buffer material at a wet thickness of about 10 m, with the CB02 coating extending about ¼″ to ½″ wider than the patch of fluorinated buffer material. The CB02 solution did not retract from the fluorinated buffer material and was dried to a uniform, coherent final film. This is shown schematically in FIG. 4, where the buffer material is indicated by the numeral 10, the uncovered ITO by the numeral 20, and the CB02 by the numeral 30.

### Example 3

A process like that described in Example 2 was used to prepare a substrate coated with fluorinated buffer material, with a similarly cleaned perimeter. This substrate had 16 regions defining pixelated displays, with anodes formed by photolithographically patterning the ITO, as shown in FIG. 5A. The substrate further had cathode separators defined by photoresist, and contact metal pads allowing bonding of electronics to the display. The thickness of the ITO was ca. 110 nm, the thickness of the photoresist was ca. 1.2 microns, and the total thickness of the contact metal regions was 500 nm. The same CB02 solution described in Example 2 was coated via slot die over this panel. The CB02 solution de-wet as it was coated over some of the display features (patterned ITO, cathode separators, or contact metal), as shown in FIG. 5B.

An identical panel was prepared, but in addition to removing the fluorinated buffer material from the perimeter of the panel the fluorinated buffer material was also removed from the perimeters of each of the displays, as shown in FIG. 6A. No de-wetting was observed from the edges of the panel, or from the edges of the displays, or from the pixel regions within the displays, as shown in FIG. 6B.

### Example 4

A substrate similar to that described in Example 3, with 16 display regions, was printed with fluorinated buffer material using a Litrex 80 ink jet printer, with a Spectra SX head. The pixel regions were separated by photoresist wells. The patterned ITO anode was ca. 110 nm thick; the photoresist pixel wells were ca. 1.2 microns thick, the cathode separators were ca. 1.2 microns thick, and the contact metal regions were ca. 500 nm thick. The cathode separators were formed on top of a portion of the pixel wells, so their total height was ca. 2.4 microns. The fluorinated buffer material was deposited in the pixel wells and did not extend up onto the tops of the photoresist wells, or onto the cathode separators, or onto the cathode separators; therefore, these regions could be wet by the organic solution. The perimeters of the displays were not cleaned. The panel was coated with the same CB02 solution as in the previous examples. No de-wetting was observed from the edges of the displays, or from the pixel regions within the displays.

Note that not all of the activities described above in the general description or the examples are required, that a portion of a specific activity may not be required, and that one or more further activities may be performed in addition to those described. Still further, the order in which activities are listed is not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

What is claimed is:

1. A process for forming a workpiece comprising a patterned first layer comprising a first material and a second layer comprising a second material, said process comprising
forming a patterned first layer having at least one pattern area having a first critical surface tension is surrounded by a second layer having a second critical surface tension greater than the first critical surface tension;
depositing a liquid composition comprising a third material in a liquid medium over the pattern area of the first layer and a portion of the second layer;
wherein said third material is deposited by a pre-metered coating method.

2. The process of claim 1, wherein the pre-metered coating method comprises using a manifold to distribute the liquid composition laterally across the first layer, with a slot to form a liquid meniscus between the manifold and the first layer.

3. The process of claim 2, wherein the coating method comprises slot die coating.

4. The process of claim 1, wherein the patterned first layer is formed by depositing discrete areas of the first material over a substrate, wherein the substrate has a critical surface tension greater than the first material critical surface tension.

5. The process of claim 4, wherein the first material is deposited from a first liquid composition comprising the first material in a liquid medium.

6. The process of claim 5, wherein the first material is deposited using a manifold to distribute the first liquid composition laterally across the substrate, with a slot to form a liquid meniscus between the manifold and the substrate.

7. The process of claim 1, wherein the patterned first layer is formed by depositing a continuous layer of first material over a substrate, and removing areas of the first material to uncover areas of the substrate surrounding areas of the first material, wherein the substrate has a critical surface tension greater than the first material critical surface tension.
